(19) United States
(12) Patent Application Publication
(10) Pub. No.: US 2026/0157200 A1
(43) Pub. Date: Jun. 4, 2026

(54) SEMICONDUCTOR PACKAGE AND METHOD FOR MANUFACTURING THE SAME

(71) Applicant: Samsung Electronics Co., Ltd., Suwon-si (KR)

(72) Inventors: Junghoo YUN, Suwon-si (KR); Seungsoo HA, Suwon-si (KR)

(73) Assignee: Samsung Electronics Co., Ltd., Suwon-si (KR)

(21) Appl. No.: 19/248,592

(22) Filed: Jun. 25, 2025

(30) Foreign Application Priority Data
Nov. 29, 2024 (KR) 10-2024-0175843

(51) Int. Cl. H01L 23/538; H01L 23/31; H01L 23/34; H01L 23/498

(52) U.S. Cl. CPC H10W 70/65; H10W 70/611; H10W 74/111; H10W 90/701; H10W 40/00

(57) ABSTRACT

A semiconductor package includes a first redistribution structure including a dielectric, a plurality of bonding pads on the dielectric, and a dummy line extending in a horizontal direction on the dielectric and the dummy line being next to the bonding pads, a semiconductor die on the plurality of the bonding pads, a plurality of conductive posts on the first redistribution structure, the plurality of conductive posts being next to the semiconductor die, a molding material covering the plurality of bonding pads, the dummy line, the semiconductor die, and the plurality of conductive posts that are on the dielectric, and a second redistribution structure on the molding material.

### CROSS-REFERENCE TO RELATED APPLICATION

This application claims priority to and the benefit of Korean Patent Application No. 10-2024-0175843 filed at the Korean Intellectual Property Office on Nov. 29, 2024, the entire contents of which are incorporated herein by reference.

### BACKGROUND

### (a) Field

The present disclosure relates to semiconductor packages and manufacturing methods thereof.

### (b) Description of the Related Art

In accordance with demand in the semiconductor industry, semiconductor dies (or semiconductor chips) are becoming lighter, thinner, smaller, faster, and/or more functional. As the semiconductor dies become lighter, thinner, smaller, faster, and/or multifunctional, the power per unit volume consumed by the semiconductor die increases, which increases the heat generated from the semiconductor die. When the heat generated in the semiconductor die is not dissipated to the outside, the heat remains within the semiconductor package including the semiconductor die, increasing the temperature of the semiconductor package Because the increase in temperature affects the operation speed of the semiconductor die, it may deteriorate product reliability of the semiconductor die.

To solve this problem, a heat dissipation structure formed of a metal material with relatively high thermal conductivity may be attached to the upper part of the semiconductor package to release the heat generated in the semiconductor die through the upper part of the semiconductor package. This method for attaching a heat dissipation structure to the upper portion of the semiconductor package is effective in improving the heat dissipation performance of the semiconductor package, but as a metal material is added to the upper portion of the semiconductor package, a difference in the metal ratio between the upper portion and the lower portion in the semiconductor package occurs, and this may worsen warpage of the semiconductor package.

In addition, to improve the heat dissipation characteristics of the semiconductor package, it is desired to reduce the thickness of the molding material placed on the semiconductor die while maintaining the thickness of the semiconductor die in the semiconductor package. On the other hand, to satisfy the warpage specifications of the semiconductor package, the thickness of the molding material needs to be increased. That is, depending on how the thickness of the molding material placed on the semiconductor die is set, the heat dissipation characteristic and the warpage characteristic of the semiconductor package produce conflicting results.

In this way, attaching the heat dissipation structure to the upper portion of the semiconductor package or reducing the thickness of the molding material placed on the semiconductor die to improve heat dissipation performance worsens the warpage of the semiconductor package. Therefore, a new technology is needed to improve the heat dissipation characteristics of the semiconductor package and to solve the warpage problem of the semiconductor package.

### SUMMARY

The present disclosure attempts to improve warpage of a semiconductor package having a structure and arrangement for improving heat dissipation characteristics without affecting the structure, arrangement, design, and/or manufacturing process of the semiconductor package.

According to an example embodiment of the present disclosure, a semiconductor package includes a first redistribution structure including a dielectric, a plurality of bonding pads on the dielectric, and a dummy line extending in a horizontal direction on the dielectric, the dummy line being next to the bonding pads, a semiconductor die on the plurality of the bonding pads, a plurality of conductive posts on the first redistribution structure, the plurality of conductive posts being next to the semiconductor die, a molding material covering the plurality of bonding pads, the dummy line, the semiconductor die, and the plurality of conductive posts that are on the dielectric, and a second redistribution structure on the molding material.

According to an example embodiment of the present disclosure, a semiconductor package includes a front side redistribution structure including a dielectric, a plurality of redistribution lines and a plurality of redistribution vias in the dielectric, a plurality of first bonding pads on the dielectric, a plurality of second bonding pads on the dielectric, the plurality of second bonding pads being next to the plurality of first bonding pads, and a dummy line extending in a horizontal direction on the dielectric, the dummy line being next to the plurality of first bonding pads, a first semiconductor die on the plurality of first bonding pads, a plurality of conductive posts each being on a corresponding second bonding pad among the plurality of second bonding pads, a molding material covering the first bonding pads, the second bonding pads, the dummy line, the first semiconductor die, and the conductive posts that are the dielectric, a back side redistribution structure on the molding material, and a second semiconductor die on the back side redistribution structure.

According to an example embodiment of the present disclosure, a method for manufacturing a semiconductor package includes forming a first redistribution structure including disposing a dielectric on a carrier, and forming a plurality of first bonding pads, a plurality of second bonding pads, and a dummy line on the dielectric, the plurality of second bonding pads being next to the plurality of first bonding pads, the dummy line extending in a horizontal direction and being next to the plurality of first bonding pads, forming a plurality of conductive posts each on a corresponding second bonding pad among the plurality of second bonding pads, mounting a semiconductor die on the plurality of first bonding pads, molding with a molding material the plurality of first bonding pads, the plurality of second bonding pads, the dummy line, the plurality of conductive posts, and the semiconductor die that are on the dielectric, and forming a second redistribution structure on the molding material.

The dummy line may be added to the empty space on the dielectric of the front side redistribution structure excluding a space in which the bonding pads are disposed, thereby adjusting warpage of the semiconductor package.

Regarding the semiconductor package including a heat dissipation structure or including a thin molding material between the semiconductor die and the back side redistribution structure, warpage of the semiconductor package may be improved while giving no influence on the structure, arrangement, design, and/or process for manufacturing a semiconductor package.

The position on which the dummy line is to be added may be selected according to the pattern of warpage of the semiconductor package, thereby locally adjusting the warpage of the semiconductor package.

### BRIEF DESCRIPTION OF THE DRAWINGS

FIG. 1 shows a cross-sectional view on a semiconductor package according to an example embodiment.

FIG. 2 shows an enlarged cross-sectional view of a region E of a semiconductor package of FIG. 1.

FIG. 3 shows a top plan view on an upper surface of a front side redistribution structure excluding a dummy line of FIG. 1.

FIG. 4 shows a top plan view on an upper surface of a front side redistribution structure of FIG. 1 according to an example embodiment.

FIG. 5 shows a top plan view on an upper surface of a front side redistribution structure of FIG. 1 according to an example embodiment.

FIG. 6 shows a top plan view on an upper surface of a front side redistribution structure of FIG. 1 according to an example embodiment.

FIG. 7 shows a top plan view on an upper surface of a front side redistribution structure of FIG. 1 according to an example embodiment.

FIG. 8 shows a cross-sectional view on a semiconductor package according to an example embodiment.

FIG. 9 shows an enlarged cross-sectional view on a region FA and a region FB of a semiconductor package of FIG. 8.

FIG. 10 shows a top plan view on an upper surface of a front side redistribution structure of FIG. 8 excluding a dummy line.

FIG. 11 shows a top plan view on an upper surface of a front side redistribution structure of FIG. 8 according to an example embodiment.

FIG. 12 shows a top plan view on an upper surface of a front side redistribution structure of FIG. 8 according to an example embodiment.

FIG. 13 shows a top plan view on an upper surface of a front side redistribution structure of FIG. 8 according to an example embodiment.

FIG. 14 shows a top plan view on an upper surface of a front side redistribution structure of FIG. 8 according to an example embodiment.

FIG. 15 to FIG. 26 show cross-sectional views on a method for manufacturing a semiconductor package according to an example embodiment of FIG. 1.

### DETAILED DESCRIPTION

The present disclosure will be described more fully hereinafter with reference to the accompanying drawings, in which some example embodiments of the disclosure are shown. As those skilled in the art would realize, the described example embodiments may be modified in various different ways, all without departing from the spirit or scope of the present disclosure.

The drawings and description are to be regarded as illustrative in nature and not restrictive, and like reference numerals designate like elements throughout the specification.

The size and thickness of each configuration shown in the drawings are arbitrarily shown for better understanding and ease of description, but example embodiments of the present disclosure are not limited thereto.

Throughout this specification and the claims that follow, when it is described that an element is “coupled” to another element, the element may be “directly coupled” to the other element or “indirectly coupled” to the other element through a third element. Unless explicitly described to the contrary, the word “comprise”, and variations such as “comprises” or “comprising”, will be understood to imply the inclusion of stated elements but not the exclusion of any other elements.

It will be understood that when an element such as a layer, film, region, or substrate is referred to as being “on” another element, it may be directly on the other element or intervening elements may also be present. In contrast, when an element is referred to as being “directly on” another element, there are no intervening elements present. The word “on” or “above” means disposed on or below the object portion, and does not necessarily mean disposed on the upper side of the object portion based on a gravitational direction.

The phrase “in a plan view” means viewing an object portion from the top, and the phrase “in a cross-sectional view” means viewing a cross-section of which the object portion is vertically cut from the side.

As used herein, expressions such as “one of,” “one or more of,” “any one of,” and “at least one of,” when preceding a list of elements, modify the entire list of elements and do not modify the individual elements of the list. Thus, for example, both “at least one of A, B, or C” and “at least one of A, B, and C” mean either A, B, C or any combination thereof. Likewise, A and/or B means A, B, or A and B.

While the term “same,” “equal” or “identical” is used in description of example embodiments, it should be understood that some imprecisions may exist. Thus, when one element is referred to as being the same as another element, it should be understood that an element or a value is the same as another element within a desired manufacturing or operational tolerance range (e.g., ±10%).

When the term “about,” “substantially” or “approximately” is used in this specification in connection with a numerical value, it is intended that the associated numerical value includes a manufacturing or operational tolerance (e.g., ±10%) around the stated numerical value. Moreover, when the word “about,” “substantially” or “approximately” is used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

A semiconductor package 100, 100A and 100B and a manufacturing method thereof according to some example embodiments will now be described with accompanying drawings.

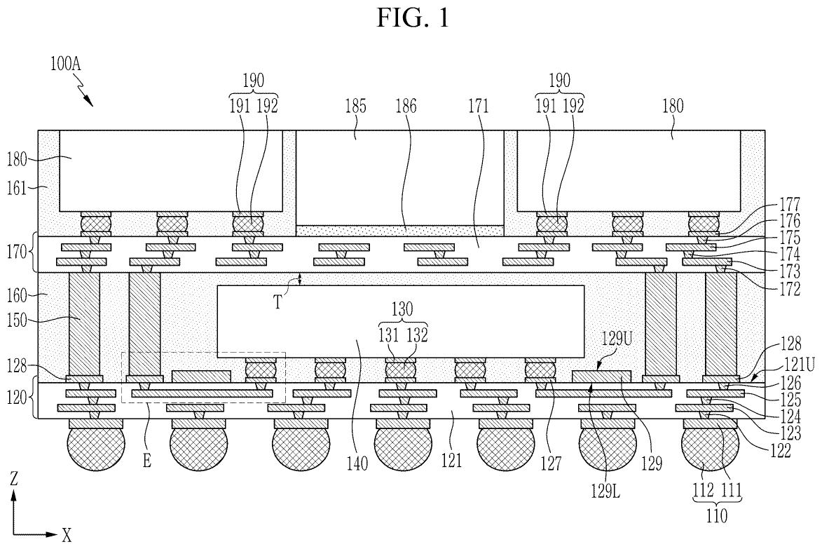

FIG. 1 shows a cross-sectional view on a semiconductor package 100A according to an example embodiment.

Referring to FIG. 1, the semiconductor package 100A may include an external connection structure 110, a front side redistribution structure (or first redistribution structure) 120, a first bump structure 130, a first semiconductor die 140, conductive posts 150, a first molding material 160, a back side redistribution structure (or second redistribution structure) 170, second semiconductor dies 180, a heat dissipation structure 185, an adhesive member 186, a second bump structure 190, and a second molding material 161. In an example embodiment, the semiconductor package 100A may include a package on package (PoP). FIG. 1 shows a package on package (PoP) as an example embodiment of the semiconductor package 100A, but example embodiments are not limited thereto. For example, a 2.5D semiconductor package, a 3D semiconductor package, and a semiconductor package in which semiconductor dies are disposed side by side in the redistribution structure may be included in the scope of the present disclosure. In an example embodiment, the semiconductor package 100A may be manufactured based on a fan out wafer level package (FOWLP) or fan out panel level package (FOPLP) technology.

The external connection structure 110 may be disposed on a lower surface of the front side redistribution structure 120. The external connection structure 110 may include conductive pads 111 and external connection members 112. Each of conductive pads 111 may electrically connect a corresponding first redistribution via 122 among the first redistribution vias 122 of the front side redistribution structure 120 to a corresponding external connection member 112 among the external connection members 112. The external connection members 112 may electrically connect the semiconductor package 100A to an external device (not shown).

The front side redistribution structure 120 may be disposed on the external connection structure 110. The front side redistribution structure 120 may include a first dielectric 121, first redistribution vias 122, first redistribution lines 123, second redistribution vias 124, second redistribution lines 125, and third redistribution vias 126 disposed in the first dielectric 121, and first bonding pads 127, second bonding pads 128, and at least one dummy line 129 disposed on the first dielectric 121. In another example embodiment, the front side redistribution structure 120 including a greater or lesser number of redistribution lines, redistribution vias, bonding pads, and dummy lines may be included in the range of the present disclosure.

The first dielectric 121 may protect and insulate the first redistribution vias 122, the first redistribution lines 123, the second redistribution vias 124, the second redistribution lines 125, and the third redistribution vias 126. The first bonding pads 127, the second bonding pads 128, the at least one dummy line 129, and the first molding material 160 may be disposed on an upper surface of the first dielectric 121. The conductive pads 111 may be disposed on a lower surface of the first dielectric 121.

The first redistribution vias 122, the first redistribution lines 123, the second redistribution vias 124, the second redistribution lines 125, and the third redistribution vias 126 may be sequentially stacked from the bottom, and may form signals, ground, and electric power routing paths. The first redistribution lines 123 and the second redistribution lines 125 may extend in a horizontal direction in the first dielectric 121. The first redistribution vias 122, the second redistribution vias 124, and the third redistribution vias 126 may extend in a perpendicular direction in the first dielectric 121. Each of first bonding pads 127 may be disposed between a corresponding third redistribution via 126 among the third redistribution vias 126 and a corresponding first solder 132 among the first solders 132. Each of first bonding pads 127 may electrically connect the corresponding first solder 132 to the corresponding third redistribution via 126 in the perpendicular direction. Each of second bonding pads 128 may be disposed between the corresponding third redistribution via 126 among the third redistribution vias 126 and the corresponding conductive post 150 among the conductive posts 150. Each of second bonding pads 128 may electrically connect the corresponding conductive post 150 to the corresponding third redistribution via 126 in the perpendicular direction.

The dummy line 129 may be disposed next to the first bonding pads 127 and the second bonding pads 128 on the first dielectric 121. One or more dummy lines 129 may be provided. The dummy line 129 may include a first surface 129U contacting the first molding material 160, and a second surface 129L that is opposite the first surface 129U and contacts the first dielectric 121. The second surface 129L may not contact the third redistribution via 126 and may only contact the first dielectric 121. The dummy line 129 may be electrically separated from the first redistribution vias 122, the first redistribution lines 123, the second redistribution vias 124, the second redistribution lines 125, the third redistribution vias 126, the first bonding pads 127, and the second bonding pads 128. In an example embodiment, the dummy line 129 may have a quadrangular cross-sectional shape.

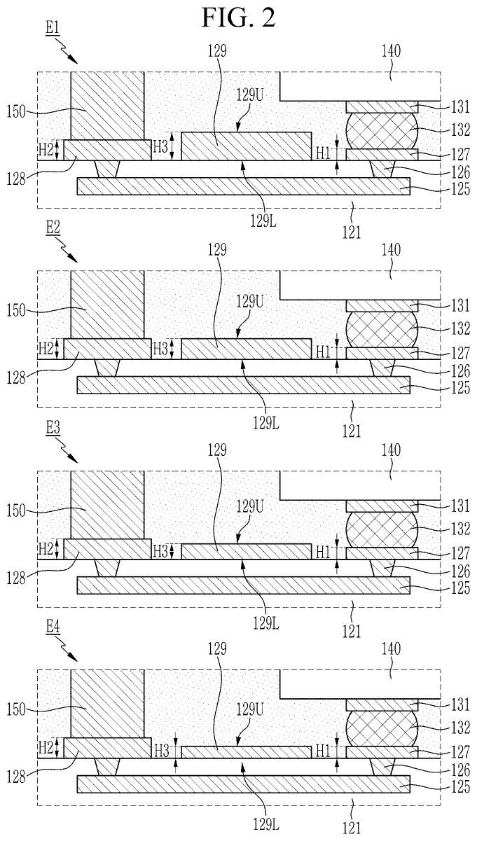

FIG. 2 shows a cross-sectional view on the dummy line 129 according to an example embodiment. FIG. 2 shows an enlarged cross-sectional view of a region E of a semiconductor package 100A of FIG. 1.

Referring to FIG. 2, the first bonding pad 127 among the first bonding pads 127 may have a first thickness H1 in the perpendicular direction (or Z direction). The second bonding pad 128 among the second bonding pads 128 may have a second thickness H2 in the perpendicular direction (or Z direction). The conductive post 150 may be disposed on the second bonding pad 128, and to reduce an aspect ratio of the conductive post 150, the second bonding pad 128 formed below the conductive post 150 may have the second thickness H2 that is greater than the first thickness H1 of the first bonding pad 127 formed below the first semiconductor die 140.

The dummy line 129 may have a third thickness H3 in the perpendicular direction (or Z direction). The third thickness H3 of the dummy line 129 may be adjusted considering an amount of a metallic material needed in reduction of warpage generated by the semiconductor package 100A. In an example embodiment, the third thickness H3 may be greater than the first thickness H1 and the second thickness H2 (see E1 of FIG. 2). The dummy line 129 may be formed by performing a process that is different from the process for forming the first bonding pads 127 and the process for forming the second bonding pads 128. In an example embodiment, the third thickness H3 may be equal to the second thickness H2 and may be greater than the first thickness H1 (see E2 of FIG. 2). When the third thickness H3 is equal to the second thickness H2, the dummy line 129 may be formed together with the second bonding pads 128 in the process for forming the second bonding pads 128. In an example embodiment, the third thickness H3 may be less than the second thickness H2 and may be greater than the first thickness H1 (see E3 of FIG. 2). The dummy line 129 may be formed by performing a process that is different from the process for forming the first bonding pads 127 and the process for forming the second bonding pads 128. In an example embodiment, the third thickness H3 may be equal to the first thickness H1 and may be less than the second thickness H2 (see E4 of FIG. 2). When the third thickness H3 is equal to the first thickness H1, the dummy line 129 may be formed together with the first bonding pads 127 in the process for forming the first bonding pads 127.

Referring to FIG. 1, the first bump structures 130 may be disposed between the front side redistribution structure 120 and the first semiconductor die 140. In an example embodiment, the first bump structures 130 may include a micro bump. Each of first bump structures 130 may include a first connection pad 131 and a first solder 132. The first connection pad 131 may be disposed between a corresponding wire among the wires of the first semiconductor die 140 and the corresponding first solder 132 among the first solders 132. The first connection pad 131 may electrically connect the corresponding wire among the wires of the first semiconductor die 140 to the corresponding first solder 132. In an example embodiment, the first connection pad 131 may include at least one of copper, aluminum, silver, tin, gold, nickel, lead, titanium, or alloys thereof. The first solder 132 may be disposed between the corresponding first bonding pad 127 among the first bonding pads 127 of the front side redistribution structure 120 and the corresponding first connection pad 131 among the first connection pads 131. The first solder 132 may electrically connect the corresponding first connection pad 131 to the corresponding first bonding pad 127. In an example embodiment, the first solder 132 may include at least one of tin, silver, lead, nickel, copper, or alloys thereof.

The first semiconductor die 140 may be disposed on the first bump structures 130. The first semiconductor die 140 may be disposed side by side with the conductive posts 150. The first semiconductor die 140 may be disposed next to the conductive posts 150. In an example embodiment, the first semiconductor die 140 may include a logic die. In an example embodiment, the first semiconductor die 140 may include a system one chip (SoC). In an example embodiment, the first semiconductor die 140 may include an application processor (AP). In an example embodiment, the first semiconductor die 140 may include at least one of a central processing unit (CPU), a graphic processing unit (GPU), a signal processor, a network processor, or a codec.

The conductive posts 150 may be disposed on the front side redistribution structure 120. The conductive posts 150 may be disposed next to the first semiconductor die 140. The conductive posts 150 may be disposed around the first semiconductor die 140. Each of conductive posts 150 may be disposed between the corresponding second bonding pad 128 among the second bonding pads 128 of the front side redistribution structure 120 and the corresponding first redistribution via 172 among the first redistribution vias 172 of the back side redistribution structure 170. Each of conductive posts 150 may electrically connect the corresponding first redistribution via 172 among the first redistribution vias 172 of the back side redistribution structure 170 to the corresponding second bonding pad 128 among the second bonding pads 128 of the front side redistribution structure 120. The conductive posts 150 may be disposed through the first molding material 160. Side surfaces of the conductive posts 150 may be surrounded by the first molding material 160.

The first molding material 160 may cover the first bonding pads 127, the second bonding pads 128, the dummy line 129, the first bump structures 130, the first semiconductor die 140, and the conductive posts 150 on the first dielectric 121. The first molding material 160 may protect the first bump structures 130, the first semiconductor die 140, and the conductive posts 150 from external environments, and therefore, electrical and/or mechanical stability of the semiconductor package 100A may be obtained.

To improve the heat dissipation characteristic of the semiconductor package 100A, it is desired to reduce the thickness T of the first molding material 160 disposed on the first semiconductor die 140. On the contrary, to satisfy the specification of warpage of the semiconductor package 100A, there is a need to increase the thickness T of the first molding material 160 between the first semiconductor die 140 and the back side redistribution structure 170. Accordingly, because the heat dissipation characteristics and the warpage characteristics of the semiconductor package 100A have conflicting results depending on how the thickness T of the first molding material 160 between the first semiconductor die 140 and the back side redistribution structure 170 is set, the setting of the thickness T of the first molding material 160 between the first semiconductor die 140 and the back side redistribution structure 170 becomes an important issue. According to an example embodiment of the present disclosure, warpage of the semiconductor package may be improved by disposing the dummy line 129 on the first dielectric 121 so the thickness (T) of the first molding material 160 between the first semiconductor die 140 and the back side redistribution structure 170 may be maintained to be relatively thin. In an example embodiment, the thickness T of the first molding material 160 between the first semiconductor die 140 and the back side redistribution structure 170 may be in the range of about 10 μm to about 40 μm.

The back side redistribution structure 170 may be disposed on the conductive posts 150 and the first molding material 160. The back side redistribution structure 170 may include a second dielectric 171, first redistribution vias 172, first redistribution lines 173, second redistribution vias 174, second redistribution lines 175, and third redistribution vias 176 in the second dielectric 171, and bonding pads 177 on the second dielectric 171. In another example embodiment, the back side redistribution structure 170 including a greater or lesser number of redistribution lines, redistribution vias, and bonding pads may be included in the range of the present disclosure.

The second dielectric 171 may protect and insulate the first redistribution vias 172, the first redistribution lines 173, the second redistribution vias 174, the second redistribution lines 175, and the third redistribution vias 176. The bonding pads 177, the adhesive member 186, and the second molding material 161 may be disposed on the upper surface of the second dielectric 171. The conductive posts 150 and the first molding material 160 may be disposed on a lower surface of the second dielectric 171.

The first redistribution vias 172, the first redistribution lines 173, the second redistribution vias 174, the second redistribution lines 175, and the third redistribution vias 176 may be sequentially stacked from the bottom, and may form signals, ground, and electric power routing paths. The first redistribution lines 173 and the second redistribution lines 175 may extend in the horizontal direction in the second dielectric 171. The first redistribution vias 172, the second redistribution vias 174, and the third redistribution vias 176 may extend in the perpendicular direction in the second dielectric 171. Each of respective bonding pads 177 may be disposed between the corresponding third redistribution via 176 among the third redistribution vias 176 and the corresponding second solder 192 among the second solder 192. Each of bonding pads 177 may electrically connect the corresponding second solder 192 to the corresponding third redistribution via 176.

The second bump structures 190 may be disposed between the back side redistribution structure 170 and the second semiconductor die 180. In an example embodiment, the second bump structures 190 may include a micro bump. Each of second bump structures 190 may include a second connection pad 191 and a second solder 192. The second connection pad 191 may be disposed between the corresponding wire among the wires of the second semiconductor die 180 and the corresponding second solder 192 among the second solders 192. The second connection pad 191 may electrically connect the corresponding wire among the wires of the second semiconductor die 180 to the corresponding second solder 192. In an example embodiment, the second connection pad 191 may include at least one of copper, aluminum, silver, tin, gold, nickel, lead, titanium, or alloys thereof. The second solder 192 may be disposed between the corresponding bonding pad 177 among the bonding pads 177 of the back side redistribution structure 170 to the corresponding second connection pad 191 among the second connection pads 191. The second solder 192 may electrically connect the corresponding second connection pad 191 to the corresponding bonding pad 177. In an example embodiment, the second solder 192 may include at least one of tin, silver, lead, nickel, copper, or alloys thereof.

The second semiconductor die 180 may be disposed on the second bump structures 190. The second semiconductor die 180 may be disposed on the back side redistribution structure 170. FIG. 1 shows the semiconductor package 100A including two second semiconductor dies 180, but example embodiments are not limited thereto. For example, the semiconductor package 100A including a greater or lesser number of the second semiconductor dies 180 may be included in the scope of the present disclosure. The second semiconductor die 180 may be electrically connected to the first semiconductor die 140 through the front side redistribution structure 120, the first bump structures 130, the conductive posts 150, the back side redistribution structure 170, and the second bump structures 190. In an example embodiment, the second semiconductor die 180 may include a memory semiconductor. In an example embodiment, the second semiconductor die 180 may include a single chip such as a DRAM or a multi-chip such as a high bandwidth memory (HBM).

The heat dissipation structure 185 may be disposed on the back side redistribution structure 170. The heat dissipation structure 185 may be attached to the back side redistribution structure 170 by the adhesive member 186. The heat dissipation structure 185 may be disposed next to the second semiconductor die 180. The heat dissipation structure 185 may be thermally connected to the back side redistribution structure 170. Heat generated by the first semiconductor die 140 or heat generated by the second semiconductor die 180 may pass through the back side redistribution structure 170 and may be transmitted to the heat dissipation structure 185. The heat dissipation structure 185 may discharge the transmitted heat to an outside of the semiconductor package 100A. In an example embodiment, the heat dissipation structure 185 may include a heat slug, a heat sink, or a heat spreader. In an example embodiment, the heat dissipation structure 185 may include a conductive material with a relatively high heat conductivity. In an example embodiment, the heat dissipation structure 185 may include at least one of copper, aluminum, silver, tin, gold, nickel, lead, titanium, or alloys thereof.

The adhesive member 186 may be disposed between the back side redistribution structure 170 and the heat dissipation structure 185. The adhesive member 186 may attach the heat dissipation structure 185 to the back side redistribution structure 170. In an example embodiment, the adhesive member 186 may include a thermal interface material TIM. The thermal interface material TIM may be inserted between the back side redistribution structure 170 and the heat dissipation structure 185, and may increase heat coupling between the back side redistribution structure 170 and the heat dissipation structure 185. The thermal interface material TIM may fill an air layer on a contacting surface between the back side redistribution structure 170 and the heat dissipation structure 185 to reduce heat contact resistance.

The second molding material 161 may cover the second semiconductor die 180, the second bump structures 190, the heat dissipation structure 185, and the adhesive member 186 on the back side redistribution structure 170. The second molding material 161 may protect the second semiconductor die 180, the second bump structures 190, the heat dissipation structure 185, and the adhesive member 186 from the external environment so that the semiconductor package 100A may obtain improved electrical and/or mechanical stability.

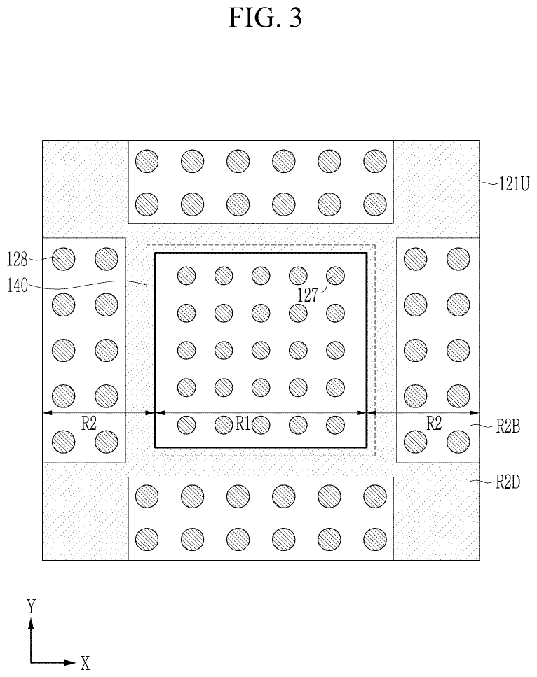

FIG. 3 shows a top plan view on an upper surface 121U of a front side redistribution structure 120 excluding a dummy line 129 of FIG. 1.

Referring to FIG. 3, the front side redistribution structure 120 may include the upper surface 121U facing the first semiconductor die 140. The first semiconductor die 140 is marked with dotted lines. The upper surface 121U of the front side redistribution structure 120 may include a center area (or first region) R1 and a peripheral area (or second region) R2. The first bonding pads 127 may be disposed in the center area R1. A footprint of the center area R1 may match a footprint of the first semiconductor die 140, or may be less than the footprint of the first semiconductor die 140. The peripheral area R2 may be disposed around the center area R1. The second bonding pads 128 may be disposed in the peripheral area R2. The peripheral area R2 may be divided into an area R2B in which the second bonding pads 128 are disposed and an area R2D in which the second bonding pads 128 are not disposed. In an example embodiment, the area R2D in which the second bonding pads 128 are not disposed may occupy about 80% to about 89% of the entire area of the upper surface 121U of the front side redistribution structure 120. To reduce the warpage generated in the semiconductor package 100A, the dummy line 129 may be disposed in the area R2D in which the second bonding pads 128 are not disposed among the peripheral area R2.

The area R2B in which the second bonding pads 128 are disposed and the area R2D in which the second bonding pads 128 are not disposed are not limited to the areas shown in FIG. 3 to FIG. 7, and the area R2B and the area R2D may be changed according to various conditions including the number, arrangement, and disposition of the first semiconductor die 140 and the second bonding pads 128, warpage degrees of the semiconductor package 100A, and/or positions where warpage of the semiconductor package 100A is generated.

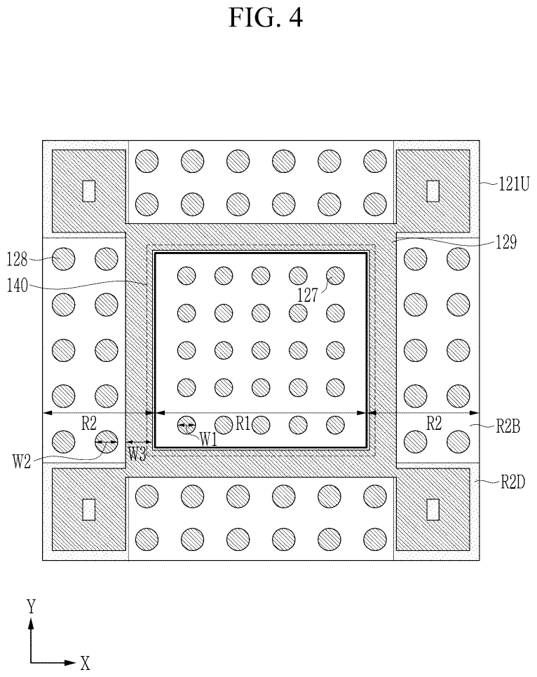

FIG. 4 shows a top plan view on an upper surface 121U of a front side redistribution structure 120 of FIG. 1 according to an example embodiment.

Referring to FIG. 4, the dummy line 129 may be disposed on at least a portion of the area R2D in which the second bonding pads 128 are not disposed among the peripheral area R2. The dummy line 129 may continuously extend around the first bonding pads 127. FIG. 4 shows one dummy line 129 that continuously extends, but example embodiments are not limited thereto. For example, the dummy line 129 may be dummy lines that are discontinuous from each other. The dummy line 129 may conformally extend along a side surface of the center area R1. The dummy line 129 may be disposed between the first bonding pads 127 and the second bonding pads 128.

Each of the first bonding pads 127 may have a first width W1 in the horizontal direction (X direction, Y direction, or the direction between X direction and Y direction). Each of the second bonding pads 128 may have a second width W2 in the horizontal direction (X direction, Y direction, or direction between X direction and Y direction). The conductive post 150 may be disposed on the second bonding pad 128, and to reduce the aspect ratio of the conductive post 150 and form the conductive post 150 on the second bonding pad 128, the second bonding pad 128 formed below the conductive post 150 may have a greater second width W2 than the first width W1 of the first bonding pad 127 formed below the first semiconductor die 140.

The dummy line 129 may have a third width W3 in the horizontal direction (X direction, Y direction, or direction between X direction and Y direction). The third width W3 of the dummy line 129 may be adjusted, considering an amount of the metallic material for reducing warpage of the semiconductor package 100A. In an example embodiment, the third width W3 may be greater than the first width W1 and the second width W2. The footprint of the dummy line 129 may overlap the footprint of the first semiconductor die 140.

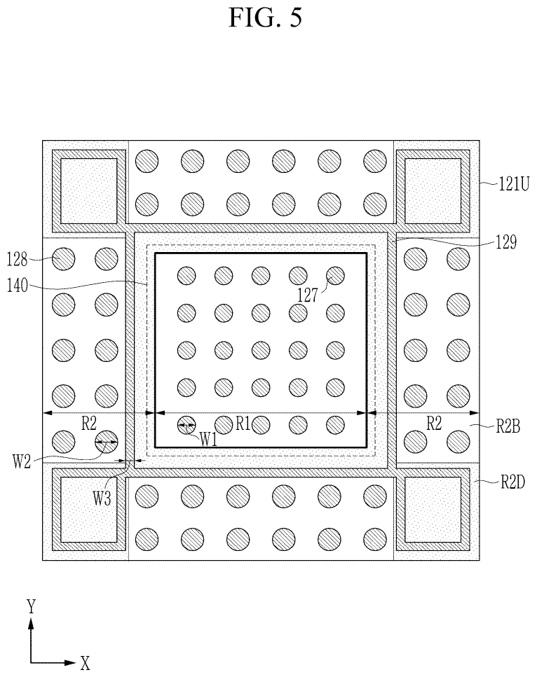

FIG. 5 shows a top plan view on an upper surface 121U of a front side redistribution structure 120 of FIG. 1 according to an example embodiment.

Referring to FIG. 5, the dummy line 129 may be disposed on at least a portion of the area R2D in which the second bonding pads 128 are not disposed among the peripheral area R2. The dummy line 129 may continuously extend around an area occupied by the first bonding pads 127. FIG. 5 shows one dummy line 129 that continuously extends, but example embodiments are not limited thereto. For example, the dummy line 129 may be dummy lines that are discontinuous from each other. The dummy line 129 may conformally extend along the side surface of the center area R1. The dummy line 129 may be disposed between the first bonding pads 127 and the second bonding pads 128.

Each of the first bonding pads 127 may have the first width W1 in the horizontal direction (X direction, Y direction, or direction between X direction and Y direction). Each of the second bonding pads 128 may have the second width W2 in the horizontal direction (X direction, Y direction, or direction between X direction and Y direction). As described above, the second bonding pad 128 may have the second width W2 that is greater than the first width W1 of the first bonding pad 127 formed below the first semiconductor die 140.

The dummy line 129 may have the third width W3 in the horizontal direction (X direction, Y direction, or direction between X direction and Y direction). The third width W3 of the dummy line 129 may be adjusted, considering the amount of the metallic material for reducing warpage of the semiconductor package 100A. In an example embodiment, the third width W3 may be shorter than the first width W1 and the second width W2.

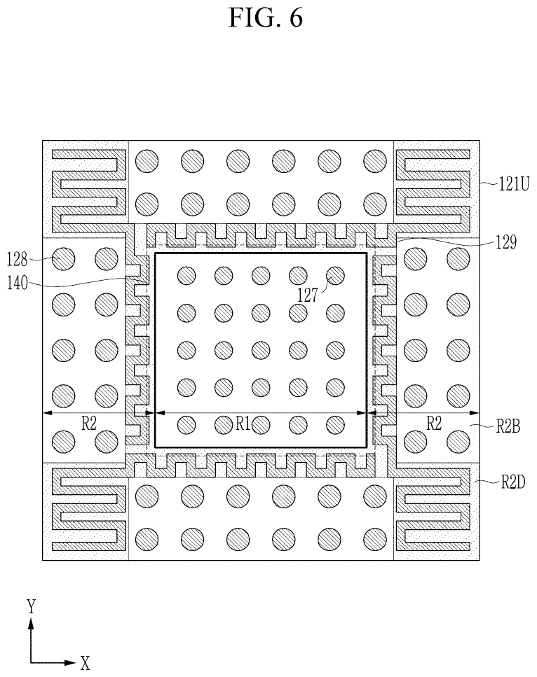

FIG. 6 shows a top plan view on an upper surface 121U of a front side redistribution structure 120 of FIG. 1 according to an example embodiment.

Referring to FIG. 6, the dummy lines 129 may be disposed on at least a portion of the area R2D in which the second bonding pads 128 are not disposed among the peripheral area R2. The dummy lines 129 may continuously extend around the first bonding pads 127. The dummy lines 129 may extend in the first horizontal direction (X direction) in an alternating fashion and in the second horizontal direction (Y direction) in an alternating fashion, the second direction (Y direction) intersecting the first horizontal direction (X direction). FIG. 6 shows dummy lines 129 that are discontinuous from each other, but example embodiments are not limited thereto. For example, the dummy line 129 may be single one that continuously extends. The dummy line 129 may be disposed between the first bonding pads 127 and the second bonding pads 128.

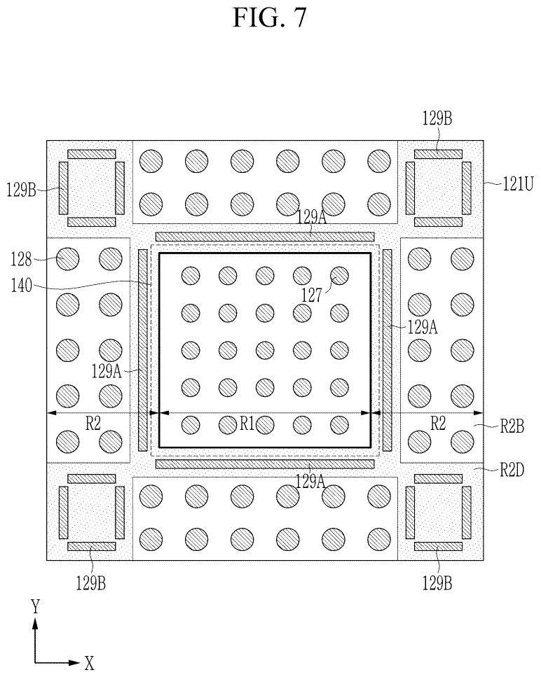

FIG. 7 shows a top plan view on an upper surface 121U of a front side redistribution structure 120 of FIG. 1 according to an example embodiment.

Referring to FIG. 7, the dummy lines 129 may be disposed on at least a portion of the area R2D in which the second bonding pads 128 are not disposed among the peripheral area R2. The dummy lines 129 may extend around an area occupied by the first bonding pads 127. Each of the dummy lines 129 may extend along the corresponding side surface among the side surfaces of the center area R1. The dummy line 129 may extend in the first horizontal direction (X direction), the second horizontal direction (Y direction), or the direction between the first horizontal direction (X direction) and the second horizontal direction (Y direction). In an example embodiment, the dummy line 129 may have an elongated shape. FIG. 7 shows the dummy lines 129 that are discontinuous from each other, but example embodiments are not limited thereto, and the dummy line 129 may be a dummy line that continuously extends. The dummy line 129 may be disposed between the first bonding pads 127 and the second bonding pads 128.

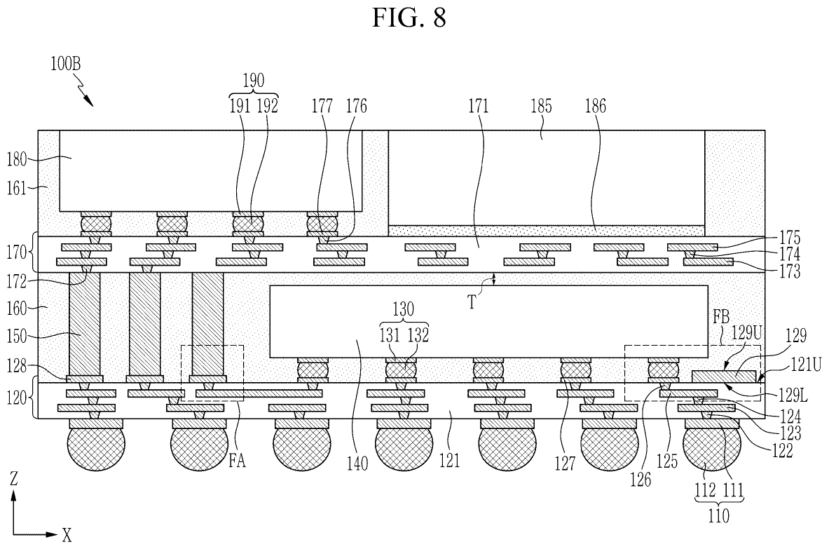

FIG. 8 shows a cross-sectional view on a semiconductor package 100B according to an example embodiment.

Referring to FIG. 8, the semiconductor package 100B may include an asymmetric structure. The conductive posts 150 may be disposed next to a side surface of the first semiconductor die 140. The second semiconductor die 180 may be disposed next to a side surface of the heat dissipation structure 185. FIG. 8 shows the semiconductor package 100B including a second semiconductor die 180 disposed next to a side surface of the heat dissipation structure 185, but example embodiments are not limited thereto. The semiconductor package 100B including a greater or lesser number of the second semiconductor dies 180 may be included in the scope of the present disclosure.

The content described on the semiconductor package 100A of FIG. 1 may be applied to contents excluding the content described on the semiconductor package 100B according to an example embodiment in FIG. 8.

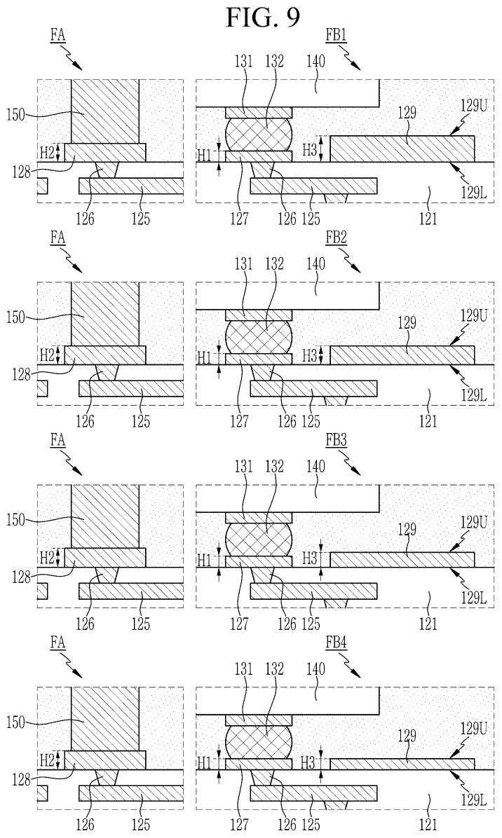

FIG. 9 shows a cross-sectional view of a dummy line 129 according to an example embodiment. FIG. 9 shows an enlarged cross-sectional view on a region FA and a region FB of a semiconductor package 100B of FIG. 8.

Referring to FIG. 9, the first bonding pad 127 may have the first thickness H1 in the perpendicular direction (or Z direction). The second bonding pad 128 may have the second thickness H2 in the perpendicular direction (or Z direction). The conductive post 150 may be disposed on the second bonding pad 128, and to reduce the aspect ratio of the conductive post 150, the second bonding pad 128 formed below the conductive post 150 may have the second thickness H2 that is greater than the first thickness H1 of the first bonding pad 127 formed below the first semiconductor die 140.

The dummy line 129 may have the third thickness H3 in the perpendicular direction (or Z direction). The third thickness H3 of the dummy line 129 may be adjusted considering the amount of the metallic material to reduce warpage of the semiconductor package 100B. In an example embodiment, the third thickness H3 may be greater than the first thickness H1 and the second thickness H2 (see FA and FB1 in FIG. 9). The dummy line 129 may be formed by performing a process that is different from the process for forming the first bonding pads 127 and the process for forming the second bonding pads 128. In an example embodiment, the third thickness H3 may be equal to the second thickness H2 and greater than the first thickness H1 (see FA and FB2 in FIG. 9). When the third thickness H3 is equal to the second thickness H2, the dummy line 129 may be formed together with the second bonding pads 128 in the process for forming the second bonding pads 128. In an example embodiment, the third thickness H3 may be less than the second thickness H2 and greater than the first thickness H1 (see FA and FB3 in FIG. 9). The dummy line 129 may be formed by performing a process that is different from the process for forming the first bonding pads 127 and the process for forming the second bonding pads 128. In an example embodiment, the third thickness H3 may be equal to the first thickness H1 and less than the second thickness H2 (see FA and FB4 in FIG. 9). When the third thickness H3 is equal to the first thickness H1, the dummy line 129 may be formed together with the first bonding pads 127 in the process for forming the first bonding pads 127.

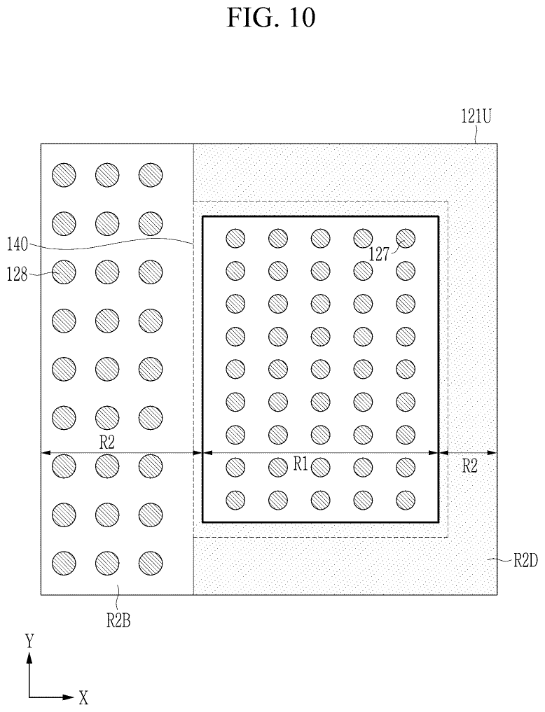

FIG. 10 shows a top plan view on an upper surface 121U of a front side redistribution structure 120 of FIG. 8 excluding a dummy line 129.

Referring to FIG. 10, the front side redistribution structure 120 may include the upper surface 121U facing the first semiconductor die 140. The first semiconductor die 140 is marked with dotted lines. The upper surface 121U of the front side redistribution structure 120 may include a center area (or first region) R1 and a peripheral area (or second region) R2. The first bonding pads 127 may be disposed in the center area R1. The footprint of the center area R1 may match the footprint of the first semiconductor die 140 or may be less than the footprint of the first semiconductor die 140. The peripheral area R2 may be disposed around the center area R1. The second bonding pads 128 may be disposed in the peripheral area R2. The peripheral area R2 may be divided into an area R2B in which the second bonding pads 128 are disposed and an area R2D in which the second bonding pads 128 are not disposed. To reduce warpage generated in the semiconductor package 100B, the dummy line 129 may be disposed in the area R2D in which the second bonding pads 128 are not disposed among the peripheral area R2.

The area R2B in which the second bonding pads 128 are disposed and the area R2D in which the second bonding pads 128 are not disposed are not limited to the areas shown in FIG. 10 to FIG. 14, and the area R2B and the area R2D may be changed according to various conditions including the number, arrangement, and/or disposition of the first semiconductor die 140 and the second bonding pads 128, warpage degrees of the semiconductor package 100B, and/or positions where warpage of the semiconductor package 100B is generated.

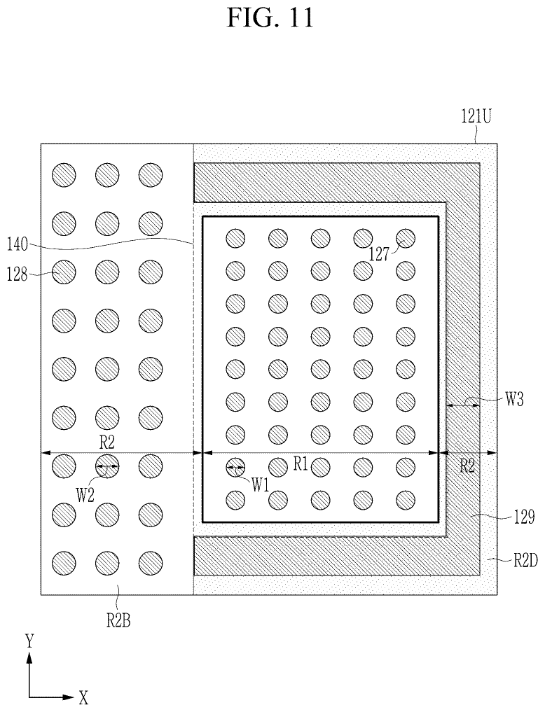

FIG. 11 shows a top plan view on an upper surface 121U of a front side redistribution structure 120 of FIG. 8 according to an example embodiment.

Referring to FIG. 11, the dummy line 129 may be disposed on at least a portion of the area R2D in which the second bonding pads 128 are not disposed in the peripheral area R2. The second bonding pads 128 may be arranged along a side surface of the center area R1. The dummy line 129 may be disposed near at least one of the other side surfaces of the center area R1. FIG. 11 shows one dummy line 129 that continuously extends, but example embodiments are not limited thereto. The dummy line 129 may be dummy lines that are discontinuous from each other. The dummy line 129 may conformally extend along at least one of the other side surfaces of the center area R1.

Each of the first bonding pads 127 may have the first width W1 in the horizontal direction (X direction, Y direction, or the direction between X direction and Y direction). Each of the second bonding pads 128 may have the second width W2 in the horizontal direction (X direction, Y direction, or the direction between X direction and Y direction). The conductive post 150 may be disposed on the second bonding pad 128, and to reduce the aspect ratio of the conductive post 150 and form the conductive post 150 on the second bonding pad 128, the second bonding pad 128 formed below the conductive post 150 may have a second width W2 greater than the first width W1 of the first bonding pad 127 formed below the first semiconductor die 140.

The dummy line 129 may have the third width W3 in the horizontal direction (X direction, Y direction, or the direction between X direction and Y direction). The third width W3 of the dummy line 129 may be adjusted, considering an amount of the metallic material for reducing warpage of the semiconductor package 100B. In an example embodiment, the third width W3 may be greater than the first width W1 and the second width W2. A footprint of the dummy line 129 may overlap a footprint of the first semiconductor die 140.

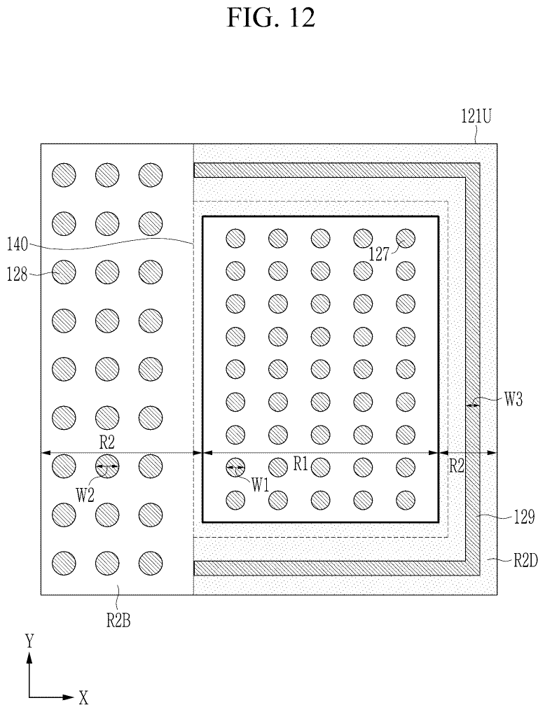

FIG. 12 shows a top plan view on an upper surface 121U of a front side redistribution structure 120 of FIG. 8 according to an example embodiment.

Referring to FIG. 12, the dummy line 129 may be disposed on at least a portion of the area R2D in which the second bonding pads 128 are not disposed in the peripheral area R2. The second bonding pads 128 may be arranged along a side surface of the center area R1. The dummy line 129 may be disposed next to at least one of the other side surfaces of the center area R1. FIG. 12 shows one dummy line 129 that continuously extends, but example embodiments are not limited thereto. The dummy line 129 may be dummy lines that are discontinuous from each other. The dummy line 129 may conformally extend along at least one of the other side surfaces of the center area R1.

Each of the first bonding pads 127 may have the first width W1 in the horizontal direction (X direction, Y direction, or the direction between X direction and Y direction). Each of the second bonding pads 128 may have the second width W2 in the horizontal direction (X direction, Y direction, or the direction between X direction and Y direction). As described above, the second bonding pad 128 may have the second width W2 that is greater than the first width W1 of the first bonding pad 127 formed below the first semiconductor die 140.

The dummy line 129 may have the third width W3 in the horizontal direction (X direction, Y direction, or the direction between X direction and Y direction). The third width W3 of the dummy line 129 may be adjusted, considering the amount of the metallic material for reducing warpage of the semiconductor package 100B. In an example embodiment, the third width W3 may be less than the first width W1 and the second width W2.

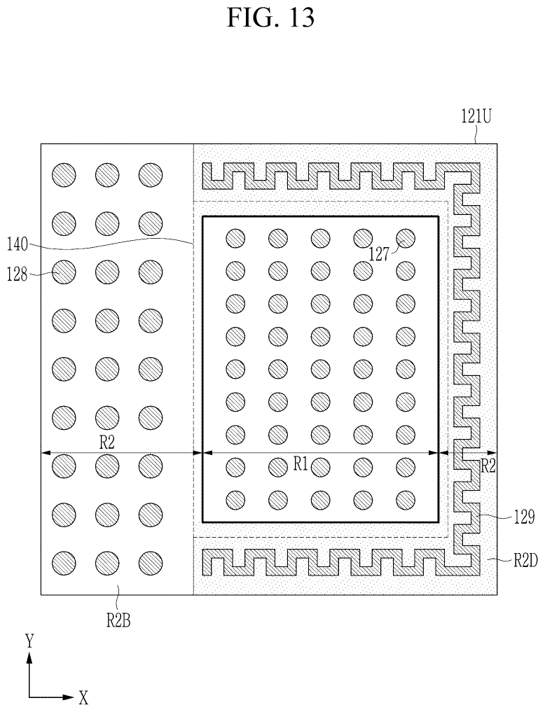

FIG. 13 shows a top plan view on an upper surface 121U of a front side redistribution structure 120 of FIG. 8 according to an example embodiment.

Referring to FIG. 13, the dummy lines 129 may be disposed on at least a portion of the area R2D in which the second bonding pads 128 are not disposed in the peripheral area R2. The second bonding pads 128 may be arranged along a side surface of the center area R1. The dummy line 129 may be disposed next to at least one of the other side surfaces of the center area R1. The dummy line 129 may extend in the first horizontal direction (X direction) in an alternating fashion and extend in the second horizontal direction (Y direction) in an alternating fashion, the second horizontal direction (Y direction) intersecting the first horizontal direction (X direction). FIG. 13 shows one dummy line that continuously extends, but example embodiments are not limited thereto. The dummy line 129 may be dummy lines 129 that are discontinuous from each other.

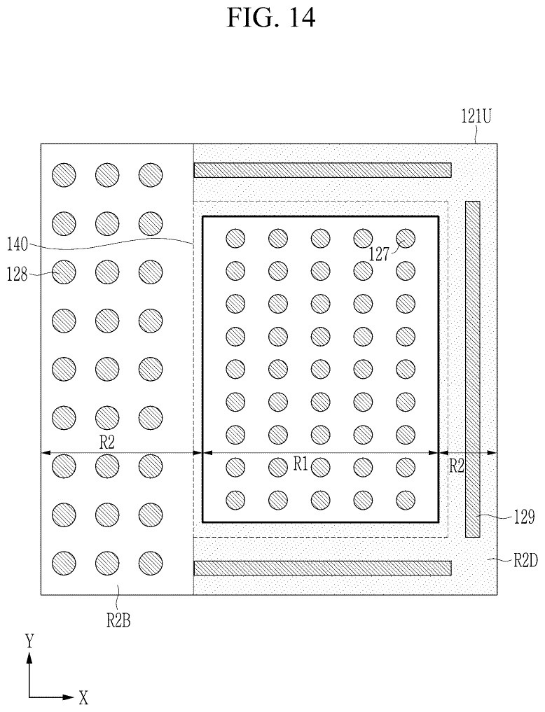

FIG. 14 shows a top plan view on an upper surface 121U of a front side redistribution structure 120 of FIG. 8 according to an example embodiment.

Referring to FIG. 14, the dummy lines 129 may be disposed on at least a portion of the area R2D in which the second bonding pads 128 are not disposed in the peripheral area R2. The second bonding pads 128 may be arranged along a side surface of the center area R1. The dummy line 129 may be disposed next to at least one of the other side surfaces of the center area R1. Each of the dummy lines 129 may extend along a corresponding side surface among the side surfaces of the center area R1. The dummy line 129 may extend in the first horizontal direction (X direction), the second horizontal direction (Y direction), or the direction between the first horizontal direction (X direction) and the second horizontal direction (Y direction). In an example embodiment, the dummy line 129 may have an elongated shape. FIG. 14 shows the dummy lines 129 that are discontinuous from each other, but example embodiments are not limited thereto. The dummy line 129 may be a dummy line that continuously extends.

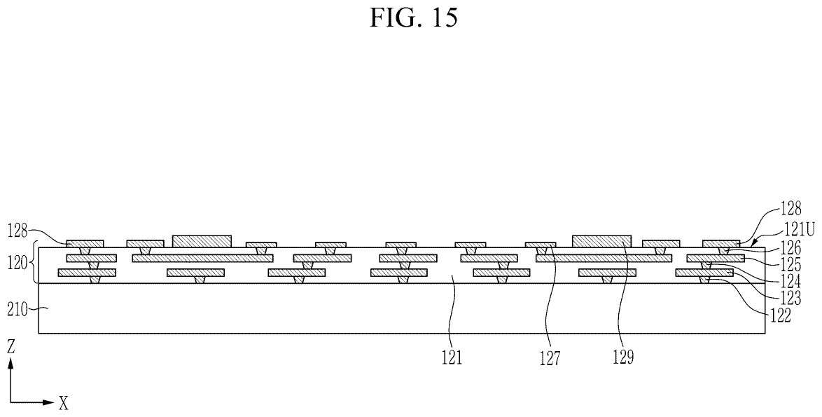

FIG. 15 to FIG. 26 show cross-sectional views on a method for manufacturing a semiconductor package 100A according to an example embodiment of FIG. 1. The method for manufacturing the semiconductor package 100A according to an example embodiment of FIG. 1 in FIG. 15 to FIG. 26 may be applied to the method for manufacturing the semiconductor package 100B of FIG. 8.

FIG. 15 shows a cross-sectional view of a process for forming a front side redistribution structure 120 on a carrier 210.

Referring to FIG. 15, the front side redistribution structure 120 may be formed on the carrier 210. In an example embodiment, the carrier 210 may include a silicon-based material such as glass or silicon oxide, other materials such as an organic material or aluminum oxide, or arbitrary combinations of the materials, and the like. The first dielectric 121 may be formed on the carrier 210, the first dielectric 121 may be selectively etched to form openings, and a conductive material is filled in the openings so that the first redistribution vias 122, the first redistribution lines 123, the second redistribution vias 124, the second redistribution lines 125, and the third redistribution vias 126 may be sequentially formed from the bottom. When the third redistribution vias 126 is formed, photoresist may be additionally deposited on the third redistribution vias 126 and the first dielectric 121, the photoresist may be selectively exposed and developed to form a photoresist pattern including openings, and a conductive material may be filled in the openings to form the first bonding pads 127, the second bonding pads 128 disposed next to the first bonding pads 127, and the dummy line 129 extending in the horizontal direction. In an example embodiment, the dummy line 129 may be formed by applying an additional pattern to the mask pattern for forming the first bonding pads 127. The first bonding pads 127 and the dummy line 129 may be simultaneously formed by a single process. In an example embodiment, the dummy line 129 may be formed by applying an additional pattern to the mask pattern for forming the second bonding pads 128. The second bonding pads 128 and the dummy line 129 may be simultaneously formed by a single process. In an example embodiment, the dummy line 129 may be formed by applying a mask pattern in addition to the mask pattern for forming the first bonding pads 127 and the mask pattern for forming the second bonding pads 128.

In an example embodiment, the first dielectric 121 may be formed as a film by performing a spin coating process. In an example embodiment, the first dielectric 121 may include photoimageable dielectrics (PID) used in the redistribution layer process. As an example embodiment, the photoimageable dielectrics (PID) may include polyimide-based photoimageable polymer, novolak-based photoimageable polymer, polybenzoxazole, silicon-based polymer, acrylate-based polymer, or epoxy-based polymer. In an example embodiment, the photoresist process and the etching process may be performed to etch the first dielectric 121 and form openings in the first dielectric 121. In an example embodiment, the first redistribution vias 122, the first redistribution lines 123, the second redistribution vias 124, the second redistribution lines 125, the third redistribution vias 126, the first bonding pads 127, the second bonding pads 128, and the dummy line 129 may be formed by performing a sputtering process or may be formed by forming a seed metal layer and then performing an electrolytic plating process. In an example embodiment, each of the first redistribution vias 122, the first redistribution lines 123, the second redistribution vias 124, the second redistribution lines 125, the third redistribution vias 126, the first bonding pads 127, the second bonding pads 128, and the dummy line 129 may include at least one of copper, aluminum, tungsten, nickel, gold, tin, titanium, or alloys thereof.

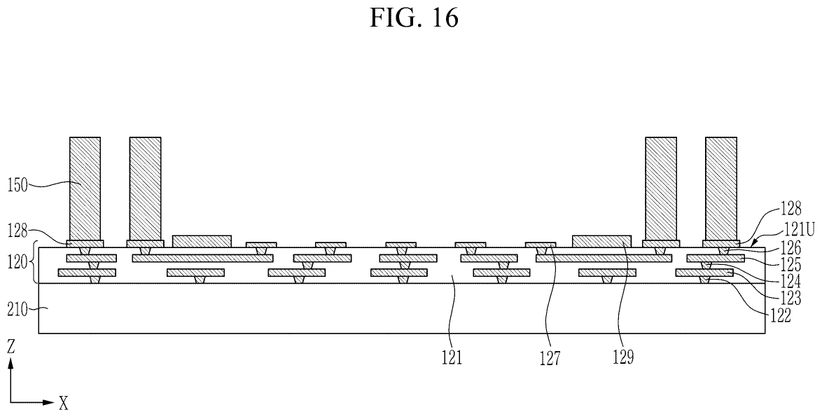

FIG. 16 shows a cross-sectional view for forming the conductive posts 150 on the second bonding pads 128.

Referring to FIG. 16, the conductive posts 150 may be formed on the second bonding pads 128 of the front side redistribution structure 120. Each of the conductive posts 150 may be formed on the corresponding second bonding pad 128 among the second bonding pads 128. The conductive posts 150 may be formed by additionally depositing photoresist in the front side redistribution structure 120, selectively exposing and developing the photoresist to form a photoresist pattern including openings, and filling the openings with a conductive material. In an example embodiment, the conductive posts 150 may be formed by performing a sputtering process or may be formed by forming a seed metal layer and then performing an electrolytic plating process. In an example embodiment, the conductive posts 150 may include at least one of copper, aluminum, tungsten, nickel, gold, silver, chromium, antimony, tin, titanium, or alloys thereof.

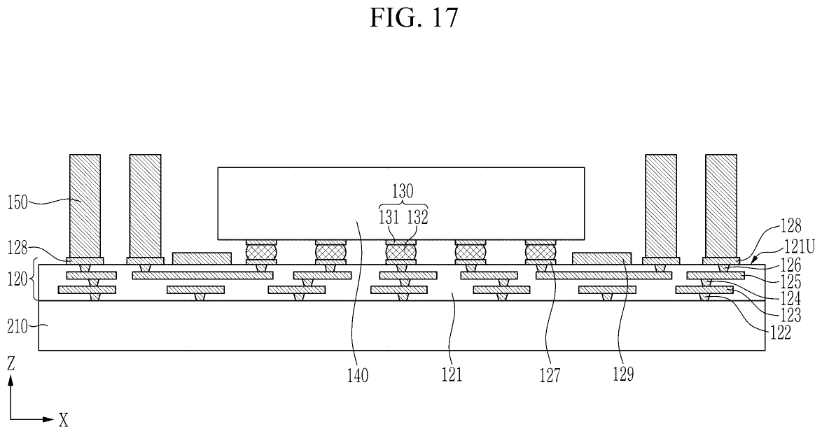

FIG. 17 shows a cross-sectional view on mounting the first semiconductor die 140 on the front side redistribution structure 120.

Referring to FIG. 17, the first semiconductor die 140 may be mounted on the front side redistribution structure 120. In an example embodiment, the first semiconductor die 140 may be bonded to the first bonding pads 127 by performing a flip chip bonding process. The first semiconductor die 140 may be bonded to the first bonding pads 127 of the front side redistribution structure 120 by the first bump structures 130 so the first semiconductor die 140 may be electrically connected to the front side redistribution structure 120.

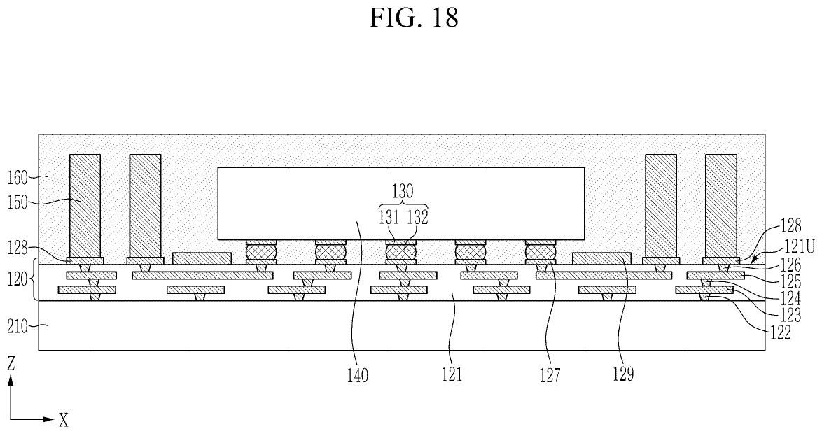

FIG. 18 shows cross-sectional views on a process for molding the first bonding pads 127, the second bonding pads 128, the dummy line 129, the first bump structures 130, the first semiconductor die 140, and the conductive posts 150 on the first dielectric 121.

Referring to FIG. 18, the first bonding pads 127, the second bonding pads 128, the dummy line 129, the first bump structures 130, the first semiconductor die 140, and the conductive posts 150 may be covered on the first dielectric 121 by the first molding material 160. As an example embodiment, the process for molding the first molding material 160 may include a compression molding process or a transfer molding process. In an example embodiment, the first molding material 160 may include an epoxy molding compound (EMC).

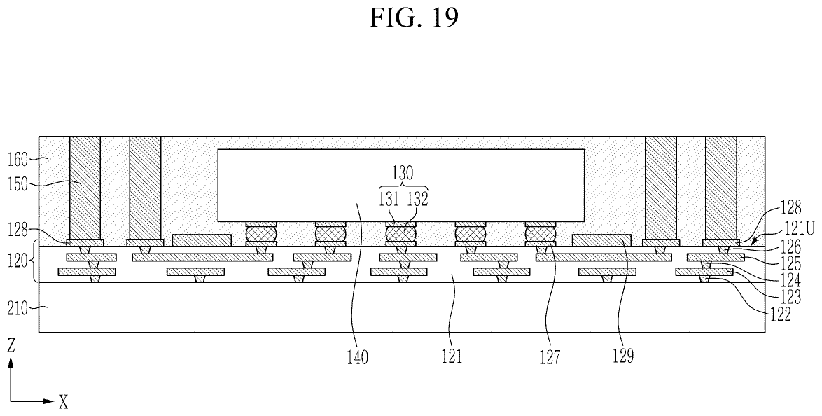

FIG. 19 shows a cross-sectional view on a process for performing a chemical mechanical polishing (CMP) on the first molding material 160.

Referring to FIG. 19, to adjust the level of the upper surface of the first molding material 160, the upper surface of the first molding material 160 may be planarized by performing a chemical mechanical polishing (CMP) process. When the chemical mechanical polishing (CMP) process is performed, the upper surface of the conductive posts 150 may be exposed.

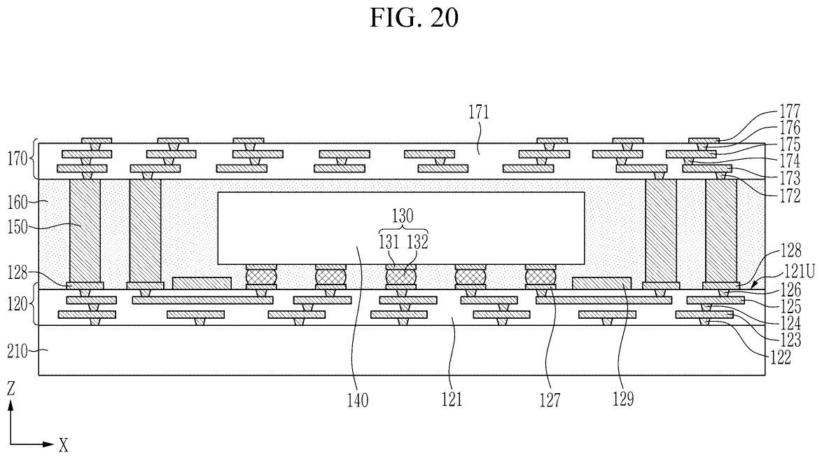

FIG. 20 shows a cross-sectional view on a process for forming the back side redistribution structure 170 on the conductive posts 150 and the first molding material 160.

Referring to FIG. 20, the back side redistribution structure 170 may be formed on the conductive posts 150 and the first molding material 160. A second dielectric 171 may be formed as a film on the conductive posts 150 and the first molding material 160. The second dielectric 171 may be selectively etched to form openings. The openings may be filled with a conductive material so that the first redistribution vias 172, the first redistribution lines 173, the second redistribution vias 174, the second redistribution lines 175, and the third redistribution vias 176 may be sequentially formed from the bottom. When the third redistribution vias 176 are formed, photoresist may be additionally deposited on the third redistribution vias 176 and the second dielectric 171. The photoresist may be selectively exposed and developed to form a photoresist pattern including openings. Then, the openings may be filled with a conductive material to form the bonding pads 177.

In an example embodiment, the second dielectric 171 may be formed as a film by performing the spin coating process. In an example embodiment, the second dielectric 171 may include photoimageable dielectrics (PID) used in the redistribution layer process. As an example embodiment, the photoimageable dielectrics (PID) may include polyimide-based photoactive polymer, novolak-based photoactive polymer, polybenzoxazole, silicon-based polymer, acrylate-based polymer, and/or epoxy-based polymer. In an example embodiment, the photoresist process and the etching process may be formed to etch the second dielectric 171 and form openings in the second dielectric 171. In an example embodiment, the first redistribution vias 172, the first redistribution lines 173, the second redistribution vias 174, the second redistribution lines 175, the third redistribution vias 176, and the bonding pads 177 may be formed by performing a sputtering process, or may be formed by forming a seed metal layer and then performing an electrolytic plating process. In an example embodiment, the first redistribution vias 172, the first redistribution lines 173, the second redistribution vias 174, the second redistribution lines 175, the third redistribution vias 176, and the bonding pads 177 may respectively include at least one of copper, aluminum, tungsten, nickel, gold, tin, titanium, or alloys thereof.

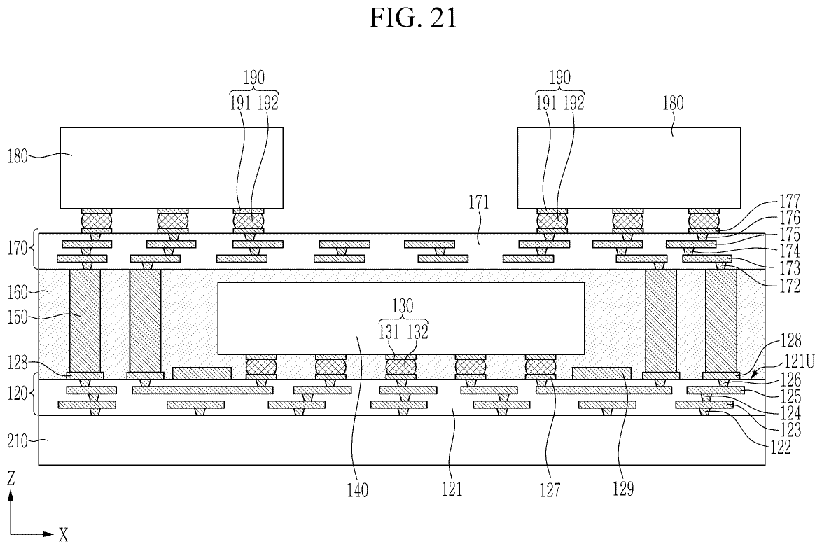

FIG. 21 shows a cross-sectional view of mounting second semiconductor dies 180 on the back side redistribution structure 170.

Referring to FIG. 21, the second semiconductor dies 180 may be mounted on the back side redistribution structure 170. In an example embodiment, the second semiconductor die 180 may be bonded to the back side redistribution structure 170 by performing a flip chip bonding process. The second solder 192 of each of the second bump structures 190 may be bonded to the corresponding bonding pad 177 among the bonding pads 177. The second semiconductor die 180 may be electrically connected to the back side redistribution structure 170 by the second bump structures 190.

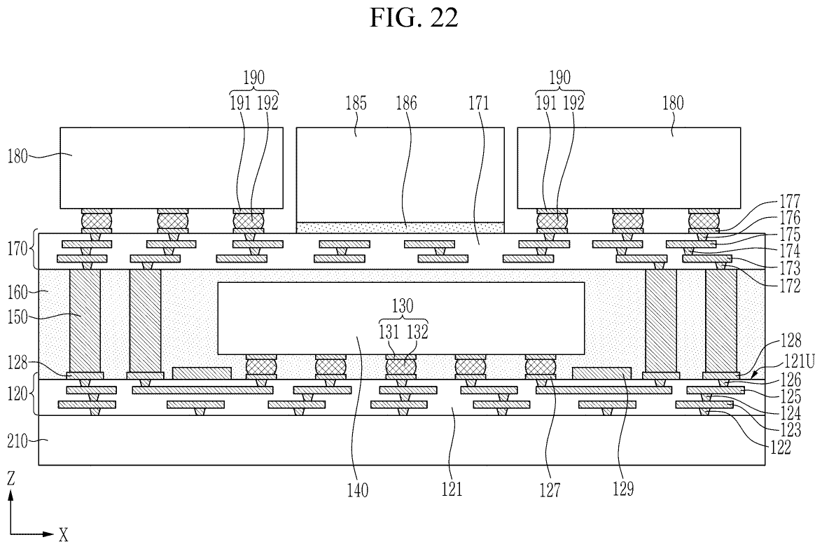

FIG. 22 shows a cross-sectional view of attaching the heat dissipation structure 185 on the back side redistribution structure 170.

Referring to FIG. 22, the heat dissipation structure 185 may be attached on the back side redistribution structure 170. The heat dissipation structure 185 may be attached to the back side redistribution structure 170 by the adhesive member 186. In an example embodiment, the adhesive member 186 may include a thermal interface material TIM. In an example embodiment, the thermal interface material TIM may include a thermal paste, a thermal pad, phase change material (PCM), a metal material, and grease.

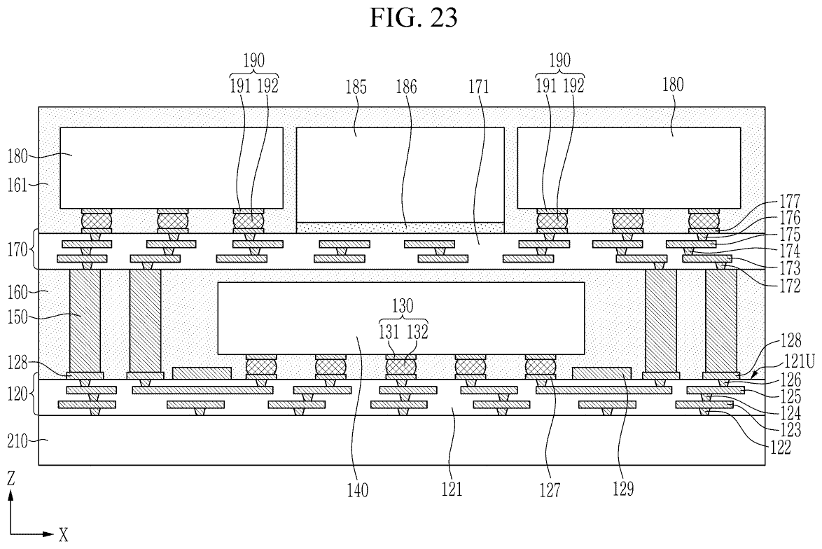

FIG. 23 shows a cross-sectional view of molding the second bump structures 190, the second semiconductor dies 180, and the heat dissipation structure 185 on the back side redistribution structure 170.

Referring to FIG. 23, the second bump structures 190, the second semiconductor dies 180, and the heat dissipation structure 185 may be covered by the second molding material 161 on the back side redistribution structure 170. In an example embodiment, the process for molding the second molding material 161 may include a compression molding or transfer molding process. In an example embodiment, the second molding material 161 may include an epoxy molding compound (EMC).

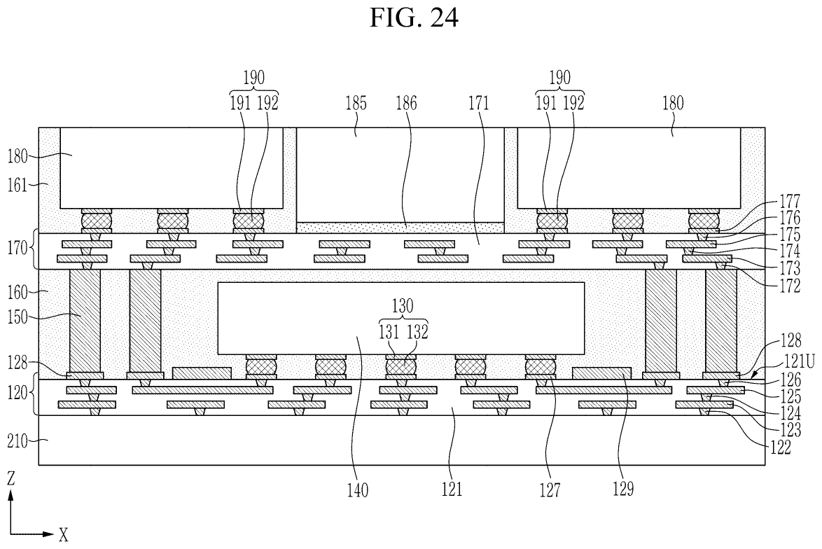

FIG. 24 shows a cross-sectional view of performing a chemical mechanical polishing (CMP) process on the second molding material 161.

Referring to FIG. 24, to adjust the level of the upper surface of the second molding material 161, the upper surface of the second molding material 161 may be planarized by performing a chemical mechanical polishing (CMP) process. When the chemical mechanical polishing (CMP) process is performed, the upper surface of the conductive posts 150 may be exposed.

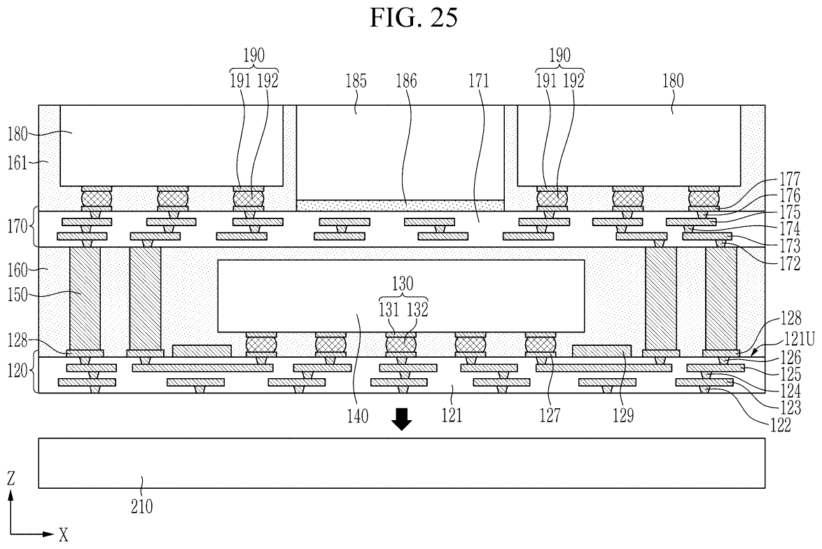

FIG. 25 shows a cross-sectional view on a process for removing the carrier 210 from the lower surface of the front side redistribution structure 120.

Referring to FIG. 25, the carrier 210 may be removed from the lower surface of the front side redistribution structure 120.

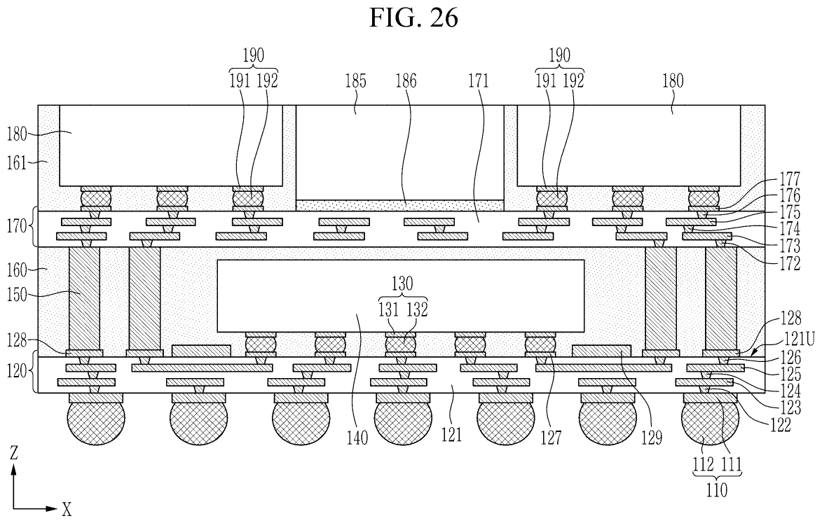

FIG. 26 shows a cross-sectional view on a process for forming external connection structures 110 on the lower surface of the front side redistribution structure 120.

Referring to FIG. 26, an external connection structure 110 may be formed on the lower surface of the front side redistribution structure 120. The conductive pads 111 may be formed below the first redistribution vias 122 of the front side redistribution structure 120. In an example embodiment, the conductive pad 111 may include at least one of copper, nickel, zinc, gold, silver, platinum, palladium, chromium, titanium, or alloys thereof. In an example embodiment, the conductive pad 111 may be formed by performing the sputtering process, or may be formed by forming a seed metal layer and then performing the electrolytic plating process. The external connection member 112 may be formed below each of the conductive pads 111. In an example embodiment, the external connection member 112 may include at least one of tin, silver, lead, nickel, copper, or alloys thereof.

While this disclosure has been described in connection with what is presently considered to be practical example embodiments, it is to be understood that the disclosure is not limited to the disclosed example embodiments, but, on the contrary, is intended to cover various modifications and equivalent arrangements included within the spirit and scope of the appended claims.

What is claimed is:

1. A semiconductor package comprising:
a first redistribution structure including
a dielectric,
a plurality of bonding pads on the dielectric, and
a dummy line extending in a horizontal direction on the dielectric, the dummy line being next to the bonding pads;
a semiconductor die on the plurality of the bonding pads;
a plurality of conductive posts on the first redistribution structure, the plurality of conductive posts being next to the semiconductor die;
a molding material covering the plurality of bonding pads, the dummy line, the semiconductor die, and the plurality of conductive posts on the dielectric; and
a second redistribution structure on the molding material.

2. The semiconductor package of claim 1, wherein
the dummy line is one dummy line that is continuous around the plurality of bonding pads.

3. The semiconductor package of claim 1, wherein a footprint of the dummy line overlaps a footprint of the semiconductor die.

4. The semiconductor package of claim 1, wherein
the dummy line includes
a first surface contacting the molding material, and
a second surface opposite to the first surface, the second surface contacting the dielectric.

5. The semiconductor package of claim 4, wherein
the second surface only contacts the dielectric.

6. The semiconductor package of claim 1, wherein
the dummy line extends in a first horizontal direction in an alternating fashion and in a second horizontal direction in an alternating fashion, the second horizontal direction intersection the first horizontal direction.

7. The semiconductor package of claim 1, wherein
the dummy line includes a plurality of dummy lines that are discontinuous from each other.

8. A semiconductor package comprising:
a front side redistribution structure including
a dielectric,
a plurality of redistribution lines and a plurality of redistribution vias in the dielectric,
a plurality of first bonding pads on the dielectric,
a plurality of second bonding pads on the dielectric, the plurality of second bonding pads being next to the plurality of first bonding pads, and
a dummy line extending in a horizontal direction on the dielectric, the dummy line being next to the plurality of first bonding pads;
a first semiconductor die on the plurality of first bonding pads;
a plurality of conductive posts each being on a corresponding second bonding pad among the plurality of second bonding pads;
a molding material covering the first bonding pads, the second bonding pads, the dummy line, the first semiconductor die, and the conductive posts that are on the dielectric;
a back side redistribution structure on the molding material; and
a second semiconductor die on the back side redistribution structure.

9. The semiconductor package of claim 8, wherein
each of the plurality of first bonding pads has a first width in the horizontal direction,
each of the plurality of second bonding pads has a second width in the horizontal direction,
the dummy line has a third width in the horizontal direction, and
the third width is greater than the second width, and the second width is greater than the first width.

10. The semiconductor package of claim 8, wherein
each of the plurality of first bonding pads has a first thickness in a perpendicular direction,
each of the plurality of second bonding pads has a second thickness in the perpendicular direction,
the dummy line has a third thickness in the perpendicular direction, and
the third thickness is greater than the second thickness, and the second thickness is greater than the first thickness.

11. The semiconductor package of claim 8, wherein
the dummy line is electrically separated from the plurality of redistribution lines and the plurality of redistribution vias.

12. The semiconductor package of claim 8, wherein
the dummy line is between the plurality of first bonding pads and the plurality of second bonding pads.

13. The semiconductor package of claim 8, wherein
the front side redistribution structure includes an upper surface facing the first semiconductor die,
the upper surface includes a first region and a second region around the first region,
the plurality of first bonding pads are in the first region, and
the plurality of second bonding pads and the dummy line are in the second region.

14. The semiconductor package of claim 13, wherein
the plurality of second bonding pads are along side surfaces of the first region.

15. The semiconductor package of claim 13, wherein
the dummy line extends along side surfaces of the first region.

16. The semiconductor package of claim 13, wherein
the second bonding pads are along a side surface of the first region.

17. The semiconductor package of claim 16, wherein
the dummy line is next to the other side surfaces of the first region.

18. The semiconductor package of claim 8, further comprising
a heat dissipation structure on the back side redistribution structure, the heat dissipation structure being next to the second semiconductor die.

19. A method for manufacturing a semiconductor package comprising:
forming a first redistribution structure including
disposing a dielectric on a carrier, and
forming a plurality of first bonding pads, a plurality of second bonding pads, and a dummy line on the dielectric, the plurality of second bonding pads being next to the plurality of first bonding pads, the dummy line extending in a horizontal direction and being next to the plurality of first bonding pads;
forming a plurality of conductive posts each on a corresponding second bonding pad among the plurality of second bonding pads;
mounting a semiconductor die on the plurality of first bonding pads;
molding with a molding material the plurality of first bonding pads, the plurality of second bonding pads, the dummy line, the plurality of conductive posts, and the semiconductor die that are on the dielectric; and
forming a second redistribution structure on the molding material.

20. The method of claim 19, wherein
the plurality of first bonding pads and the dummy line, or the plurality of second bonding pads and the dummy line are simultaneously formed by a single process.
